(19) United States
(12) Patent Application Publication
(10) Pub. No.: US 2010/0225333 A1
(43) Pub. Date: Sep. 9, 2010

(54) EXCITATION PHASE DETECTING CAPACITANCE-TYPE POSITION TRANSDUCER

(75) Inventors: Hiroyuki UCHIDA, Minamitsuru-gun (JP); Mitsuyuki TANIGUCHI, Minamitsuru-gun (JP); Shunichi ODAKA, Minamitsuru-gun (JP); Isao KARIYA, Minamitsuru-gun (JP)

Correspondence Address: LOWE HAUPTMAN HAM & BERNER, LLP, 1700 DIAGONAL ROAD, SUITE 300, ALEXANDRIA, VA, 22314, US

(73) Assignee: FANUC LTD, Minamitsuru-gun (JP)

(21) Appl. No.: 12/624,939

(22) Filed: Nov. 24, 2009

(30) Foreign Application Priority Data
Mar. 9, 2009 (JP) 2009-055649

(51) Int. Cl. G01R 27/26

(52) U.S. Cl. 324/658

(57) ABSTRACT

An excitation phase detecting capacitance-type position transducer comprises a stationary part having a plurality of excitation electrode groups and a movable part having a plurality of coupling electrodes. The capacitance-type position transducer detects a signal of which phase varies according to the relative positions of the movable part with respect to the stationary par and calculates an intra-period phase angle φ from two excitation signals having a phase difference of 90° captured at a zero-cross point of the detection signal.

### BACKGROUND OF THE INVENTION

1. Field of the Invention

The present invention relates to a excitation phase detecting capacitance-type position transducer, configured to obtain relative position information on a movable part that rotates or linearly moves relative to a stationary part, from the movable part, and obtain high-resolution signals by interpolating the position information.

2. Description of the Related Art

A capacitance-type transducer for detecting movement information on a movable part can acquire the movement information on the movable part with high sensitivity using high-frequency signals. This transducer uses principle of electrostatic capacitory coupling so that its electrode structure may be thinned, therefore, the transducer can be miniaturized.

A capacitance-type transducer disclosed in Japanese Patent Application Laid-Open No. 61-105421 includes a rotating plate rotatably mounted on its main body by a rotating shaft and a fixed plate mounted on the main body so as to face the rotating plate. This transducer detects a rotational displacement of the rotating plate relative to the fixed plate. A plurality of radially extending transmitting electrodes are arranged at regular intervals on a surface of the fixed plate. Sine-wave or rectangular-wave voltages with predetermined phases (e.g., π/4) that are shifted sequentially from one another are applied to the transmitting electrodes by a voltage application circuit. A plurality of unit electrode groups, each including eight-phase transmitting electrodes as a unit, are formed on the fixed plate. Receiving electrodes as many as the unit electrode groups are arranged on a surface of the rotating plate, and they are opposed to predetermined continuous ones of the transmitting electrodes in each unit electrode group.

In a capacitance-type transducer, in general, a plurality of excitation electrode plates are arranged at regular intervals, coupling electrodes are arranged opposite the excitation electrodes, and AC voltages with a predetermined phase shifted are applied to the excitation electrodes. The amounts of relative movement of the excitation electrodes with respect to the coupling electrodes are obtained by analyzing phase differences between capacitance signals, detected from the coupling electrodes, and the applied AC voltages. Since the capacitance-type transducer is small and light in weight and can detect the position of a movable part such as a rotor with high accuracy, its essentiality to position detection is increasing.

### SUMMARY OF THE INVENTION

Accordingly, the object of the present invention is to provide a excitation phase detecting capacitance-type position transducer, capable of obtaining position data with higher resolution based on excitation signals and signals obtained from a movable part.

In order to achieve the above object, a capacitance-type position transducer according to the invention comprises a stationary part and a movable part, and the movable part faces the stationary part and configured to move relative to the stationary part. The stationary part includes a plurality of excitation electrode groups, each composed of a plurality of excitation electrodes arranged cyclically and electrically independent of one another, and a receiving electrode electrically independent of the excitation electrode groups. The movable part includes a plurality of coupling electrodes which face the excitation electrode groups and are arranged cyclically and a transmitting electrode which is electrically connected with all the coupling electrodes and faces the receiving electrode. A signal of which the phase changes depending on relative positions of the movable part with respect to the stationary part is detected as a detection signal from the receiving electrode when a plurality of excitation signals of the same frequency and different phases are applied individually to the plurality of excitation electrodes. The capacitance-type position transducer further comprises phase difference calculating means for calculating a phase difference between the detection signal and an arbitrarily selected one of the excitation signals, based on the values of the plurality of excitation signals at a point in time the phase of the detection signal attains the characteristic point, and position calculating means for calculating a position of the movable part relative to the stationary part from the phase difference calculated by the phase difference calculating means.

The phase difference calculating means may calculate the phase difference between the detection signal and the arbitrarily selected excitation signal, based on values of two of the excitation signals with a phase difference therebetween of neither 0° nor 180°, at a point in time the phase of the detection signal attains the characteristic point.

The characteristic point of the phase of the detection signal may be a zero-cross point at which a signal obtained by removing a DC component from the detection signal changes from negative to positive, and the two of the excitation signals with a phase difference therebetween of neither 0° nor 180° are two excitation signals with a phase difference therebetween of 90°. In this case, the phase difference calculating means can directly obtain the above-mentioned ‘phase difference’ from the values of these two excitation signals detected when the detection signal is at 0° (or a detection reference phase).

The capacitance-type position transducer may further comprise first storage means for storing the number of frequencies of the excitation electrode groups corresponding to the position of the movable part relative to the stationary part and second storage means for storing position data on the movable part within the excitation electrode groups, and on the condition that the amount of movement of the movable part during a time interval for the position calculating means to calculate the position of the movable part is less than half the period of each of the excitation electrode groups, (a) if a position variation obtained by subtracting immediately previously calculated position data on the movable part, stored in the second storage means, from the last calculated position data is more than a negative half of and less than a positive half of an arrangement cycle of the excitation electrode groups, then the data stored in the second storage means is updated to last calculated position data on the movable part without updating the data stored in the first storage means, (b) if the position variation is not more than the negative half of the arrangement cycle of the excitation electrode groups, then one period is added to the data stored in the first storage means, and, (c) if the position variation is not less than the positive half of the arrangement cycle of the excitation electrode groups, then one period is subtracted from the data stored in the first storage means and the data stored in the second storage means is updated to the last calculated position data, whereby the position of the movable part is obtained based on the frequencies stored in the first storage means and the last calculated position data.

According to the present invention arranged in this manner, there may be provided a excitation phase detecting capacitance-type position transducer, capable of obtaining position data with higher resolution based on excitation signals and signals obtained from a movable part.

### BRIEF DESCRIPTION OF THE DRAWINGS

The above and other objects and features of the present invention will be obvious from the ensuing description of embodiments with reference to the accompanying drawings, in which:

FIG. 1 is a view illustrating an example of a stationary part used in a rotary capacitance-type position transducer according to one embodiment of the invention;

FIG. 2 is a view illustrating an example of a movable part used in association with the stationary part of FIG. 1;

FIG. 3 is a diagram illustrating the rotary capacitance-type position transducer according to the one embodiment of the invention using stationary part of FIG. 1 and the movable part of FIG. 2;

FIG. 4 is a schematic block diagram showing an example a position detection circuit used in the capacitance-type position transducer of FIG. 3;

FIG. 5 is a diagram showing evaluation excitation signals V_{AO} and V_{BO} as reference signals and an amplified detection signal V_{SIG};

FIGS. 6A to 6C are diagrams illustrating a method for obtaining the phase differences between the detection signal V_{SIG} and the evaluation excitation signals V_{AO} and V_{BO} based on the detection signal V_{SIG};

FIG. 7 is a flowchart showing an algorithm of processing for obtaining digital data on the evaluation excitation signals, executed by a sampling circuit shown in FIG. 3;

FIG. 8 is a flowchart showing an algorithm of processing for detecting the position of the movable part, executed for each predetermined period by the position transducer of FIG. 3;

FIG. 9 is a diagram illustrating a stationary part of a linear-motion capacitance-type position transducer;

FIG. 10 is a diagram illustrating a movable part of the linear-motion capacitance-type position transducer;

FIG. 11 is a diagram showing an outline of the linear-motion capacitance-type position transducer having the stationary part of FIG. 9 and the movable part of FIG. 10; and

FIG. 12 is a diagram illustrating generation of 90°-difference signals by three-phase excitation.

### DETAILED DESCRIPTION OF THE PREFERRED EMBODIMENTS

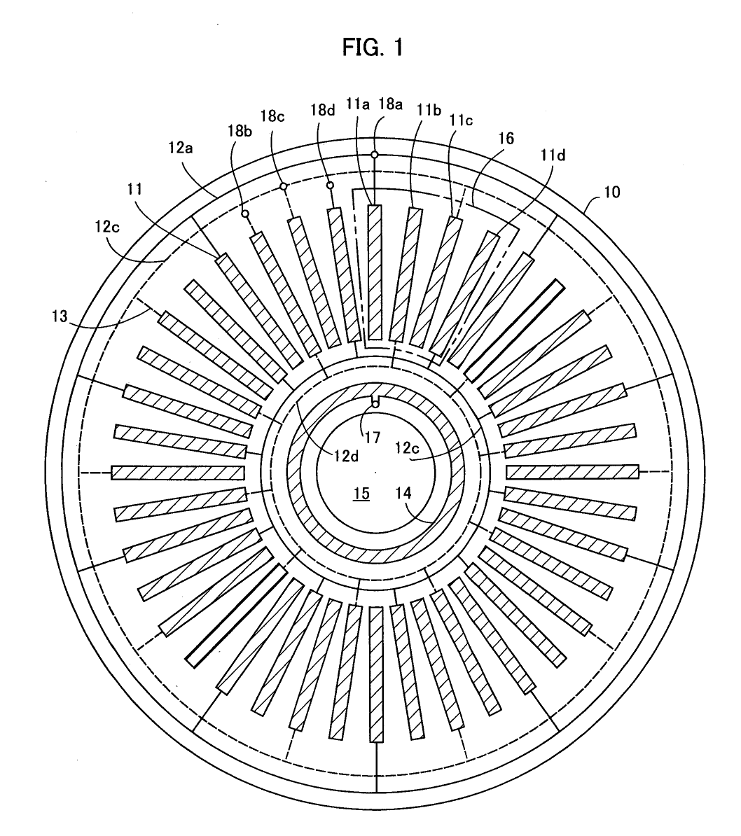

FIG. 1 is a view illustrating a stationary part used in a rotary capacitance-type position transducer according to one embodiment of the present invention.

A stationary part 10 is a disk-shaped fixed plate having a through-hole 15 in the center. A plurality of excitation electrodes 11 are arranged at regular intervals on one surface of the stationary part 10 so as to extend radially relative to the stationary part. These excitation electrodes 11 are electrically connected with one another at a constant cycle (every fifth excitation electrode 11, in this example as shown in FIG. 1).

It is required that the stationary part 10 only be made of a rigid board material with an insulating surface. For example, it may be made of a glass-epoxy material, a paper-Bakelite laminate, a ceramic such as glass or alumina, or a metal plate of iron or aluminum or a semiconductor plate of silicon with a ceramic thermally sprayed thereon, coated with an insulating resin, or insulated with an air layer in which insulating beads are arranged.

Each conductor, such as each excitation electrode 11 of the stationary part 10, can be formed by photo-etching a conductive material, such as rolled copper foil or vapor-deposited chromium, or by ink-jetting, silk screening, or offset printing using conductive ink that contains silver or carbon.

In the example of the stationary part 10 shown in FIG. 1, four excitation electrodes 11 (first, second, third and fourth excitation electrodes 11a, 11b, 11c and 11d) constitute an excitation electrode group 16, and ten such excitation electrode groups 16 are formed in total. The same-numbered excitation electrodes (e.g., excitation electrodes 11a) included in the individual excitation electrode groups 16 are electrically connected to one another by wires which are shown by solid lines or broken lines in FIG. 1. In FIG. 1, wires shown by the solid lines are arranged on the same plane as the plane where excitation electrodes 11 are arranged, whereas wires shown by the broken lines are arranged on a plane opposite the plane where excitation electrodes 11 are arranged.

In the example shown in FIG. 1, every fifth excitation electrode 11 are electrically connected with one another through electric conductors 12a, 12b 12c and 12d and feed conductors 13. The excitation electrodes 11a to 11d of four phases are excited by four-phase excitation means. The four excitation electrodes 11a to 11d that constitute each excitation electrode group 16 are electrically independent of one another. Therefore, the excitation electrodes 11 of the excitation electrode groups 16 are electrically connected by electrically connecting the electrodes 11, ring-shaped electric conductors 12, and feed conductors 13, based on a through-hole technique. The through-hole technique is a technique generally used as a printed board manufacturing technique.

Further, a ring-shaped receiving electrode 14, which is electrically independent of the excitation electrodes 11, is disposed on the central part of that surface of the stationary part 10 on which the electrodes 11 are formed. The receiving electrode 14 has a detection signal output portion 17 for outputting received detection signals to the outside.

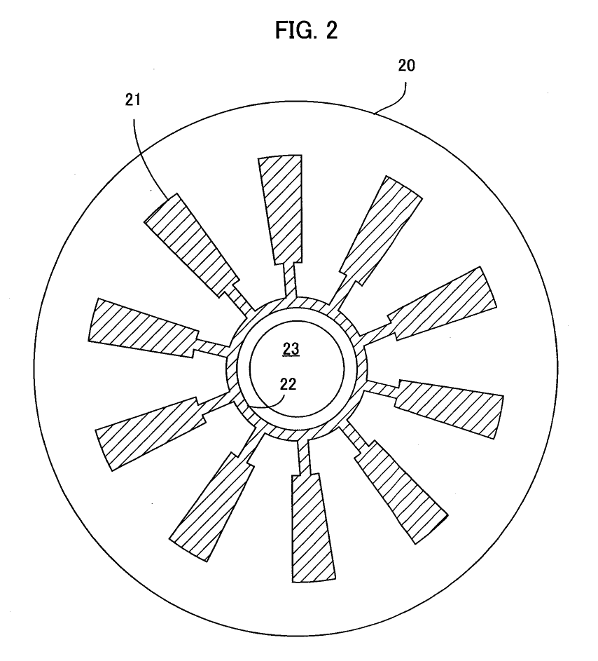

In the example shown in FIG. 1, the receiving electrode 14 is located on the same plane as the plane where the excitation electrodes 11 are located. Since the receiving electrode 14 is required to only be able to be capacitance-coupled to a transmitting electrode 22 of a movable part 20 (mentioned later) and receive the detection signals, however, it is not necessary for the receiving electrode 14 to be located on the same plane as the plane where the excitation electrodes 11 are located, thereby allowing the receiving electrode 14 to be located on a plane opposite the plane where the excitation electrodes 11 are located. Further, the receiving electrode 14 is disposed inside the excitation electrodes 11 so that the receiving electrode 14 may face the transmitting electrode 22 (FIG. 2) of the movable part 20. In case where the transmitting electrode 22 of the movable part 20 is located outside the excitation electrodes 11, the receiving electrode 14 is disposed outside the excitation electrodes 11 so that the receiving electrode 14 may face the transmitting electrode 22. The through-hole 15, which penetrates through the central part of the stationary part 10, does not need to be formed if unnecessary, since it is not essential to the capacitance-type position transducer.

FIG. 2 is a view illustrating the movable part used in the rotary capacitance-type position transducer according to the one embodiment of the present invention.

The movable part 20 is a disk-shaped rotating plate having a through-hole 23 in the center. A plurality of coupling electrodes 21 are arranged at regular intervals on one surface of the movable part 20 so as to extend radially relative to the movable part. In the example shown in FIG. 2, the coupling electrodes 21 are ten in number. All these coupling electrodes 21 are electrically connected to the ring-shaped transmitting electrode 22 on the central part of the movable part 20, and they constitute a single-phase detection electrode.

The stationary part 10 and the coupling electrodes 21 are positioned so that the surface of stationary part 10 on which the excitation electrodes 11 faces the surface of the movable part 20 on which the coupling electrodes 21 are formed. The detection electrode composed of the coupling electrodes 21 on the movable part 20 detects excitation signals applied to the excitation electrodes 11 on the side of the stationary part 10, based on the principle of electrostatic induction. The signals detected by the detection electrode composed of the coupling electrodes 21 vary depending on the positional relationship between the movable part 20 and the stationary part 10 and the combination of the excitation electrodes 11 and the excitation signals applied by the excitation means.

The single-phase AC signals detected by the detection electrode composed of the coupling electrodes 21 of the movable part 20 are transmitted from the transmitting electrode 22 on the movable part 20 to the receiving electrode 14 on the stationary part 10 by electrostatic induction between the electrodes 22 and 14. The transmitting and receiving electrodes 22 and 14 can transfer the detection signals in a non-contact manner. The detection signals may also be transferred from the movable part 20 to the stationary part 10 side through means such as a slip ring or rotary transformer, as well as through an electrostatic induction.

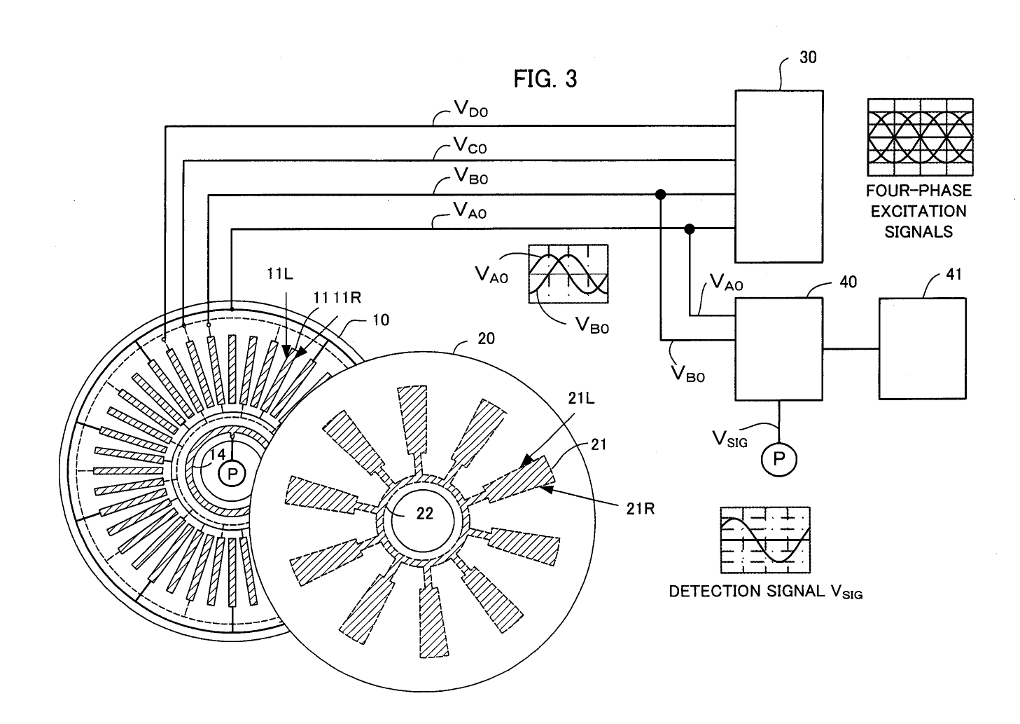

The rotary capacitance-type position transducer according to the one embodiment of the present invention using the stationary part of FIG. 1 and the movable part of FIG. 2 will now be described with reference to FIG. 3.

An excitation power source 30, which serves to output a four-phase AC voltage, is composed of a four-phase AC signal generator, an amplifier for amplifying the output of the signal generator, etc. Four-phase excitation signals (four-phase AC voltages) V_{AO}, V_{BO}, V_{CO} and V_{DO}, whose phases are shifted by a quarter period from one another, are output from the excitation power source 30 to the excitation electrodes 11a to 11d of the stationary part 10 through signal input portions (feeding portions 18a, 18b, 18c and 18d of the individual phases) of the stationary part 10. Of the four-phase AC voltages V_{AO} to V_{DO} from the excitation power source 30, moreover, the two voltages or signals V_{AO} and V_{BO} are input as evaluation excitation signals to a sampling circuit 40. The excitation signals to be input to the sampling circuit 40 will hereinafter be, referred to as “evaluation excitation signals”. The feeding portions 18a to 18d are formed by using the through-hole technique.

The stationary part 10 has forty (4×10) excitation electrodes 11, which are electrically connected to one another at regular intervals. As the four-phase AC voltages V_{AO} to V_{DO} from the excitation power source 30 are applied to the mutually connected excitation electrodes 11a to 11d, respectively, the excitation electrodes 11 of the stationary part 10 are excited, whereby a traveling-wave voltage of a predetermined phase is generated on a surface of the stationary part 10.

The movable part 20 has a single-phase detection electrode (transmitting electrode 22) electrically connected with the ten coupling electrodes 21. The detection electrode detects signals transmitted from the excitation electrodes 11 of the stationary part 10 by electrostatic induction. The signals detected by the detection electrode vary depending on the degree of coupling between electric charge on the excitation electrodes 11 of different phases and the coupling electrodes 21 that constitute the detection electrode. The result of synthesis of the detected signals appears as a single-phase AC voltage of a phase that is determined in accordance with the relative angular positions of the movable part 20 with respect to the stationary part 10. If the movable part 20 rotates an amount corresponding to the number of phases (four phases) of the excitation electrodes 11 that constitute the excitation electrode group 16, a single-phase AC voltage of the same phase as the first one is generated. If the movable part 20 further moves, a change of that phase is repeated.

The movable part 20 is supported by a mechanical section (not shown) so as to be rotatable coaxially with the stationary part 10 and so that its surface on which the coupling electrodes 21 are arranged faces the excitation electrodes 11 of the stationary part 10 with a predetermined gap between them. In FIG. 3, the contour of the coupling electrodes 21 of the movable part 20 is represented by broken line in order to indicate that the coupling electrodes 21 are arranged behind the drawing sheet of FIG. 3. The gap between the excitation electrodes 11 of the stationary part 10 and the surface of the movable part 20 on which the coupling electrodes 21 are arranged is generally set to be about 150 to 200 μm if the excitation electrodes 11 are arranged at a pitch of 200 μm, for example. In FIG. 3, the stationary part 10 and the movable part 20 are not shown to be coaxial for ease of illustration only.

Since the excitation electrodes 11 faces the coupling electrodes 21 for electrostatic capacitory coupling between them, as mentioned before, voltages corresponding to the degree of electrostatic capacitory coupling between the excitation electrodes 11 and the coupling electrodes 21 appear at the transmitting electrode 22 that is electrically connected to the coupling electrodes 21. Since the transmitting electrode 22 of the movable part 20 faces the receiving electrode 14 of the stationary part 10, moreover, a voltage corresponding to the degree of electrostatic capacitory coupling between the receiving electrode 14 and the transmitting electrode 22 appears as a detection signal V_{SIG} at the receiving electrode 14. The detection signal V_{SIG} detected by the receiving electrode is input to the sampling circuit 40. Here, it should be noted that symbol ‘P’ in FIG. 3 simply indicates an electric connection using an electric wire or the like. The detection signal V_{SIG} becomes an AC voltage having the same frequency as the voltages applied to the excitation electrodes 11. If the frequency of the excitation electrodes 11 is 1 MHz, for example, the detection signal V_{SIG} also becomes an AC voltage of 1 MHz. If necessary, the detection signal V_{SIG} detected by the receiving electrode 14 is amplified by amplifying means (not shown).

The sampling circuit 40 comprises a comparator and a differentiating circuit for detecting a zero-cross point at which the detection signal V_{SIG} changes from negative to positive. Further, the sampling circuit 40 comprises a sample-and-hold circuit and an A/D converter for acquiring digital data on the evaluation excitation signals V_{AO} and V_{BO} at a characteristic point of the detection signal V_{SIG}.

The sampling circuit 40 detects the evaluation excitation signals V_{AO} and V_{BO} at a “point in time the phase of the detection signal V_{SIG} attains the characteristic point” and obtains digital data V_{A} and V_{B} on the signals V_{AO} and V. The obtained digital data V_{A} and V_{B} are output to a position detection circuit 41. The “point in time the phase of the detection signal V_{SIG} attains the characteristic point” is, for example, a zero-cross point at which the detection signal V_{SIG} changes from negative to positive or from positive to negative. In consideration of the zero-cross point, according to the present embodiment, “two excitation signals with a phase difference not 180°” of the multiphase excitation power source are sampled as evaluation excitation signals V_{AO} and V_{BO} when the detection signal V_{SIG} attains the phase (detection reference phase). Sine- and cosine-wave signals are obtained based on the sampled signals V_{AO} and V_{BO}. Two excitation signals with a phase difference of 90° are effectively available as the “two excitation signals with a phase difference not 180°”, since they serve directly as sine- and cosine-wave signals. In sampling two signals with a phase difference not 90°, moreover, sine- and cosine-wave signals can be obtained by multiplying those two sampled signals by a predetermined coefficient and adding up the resulting products.

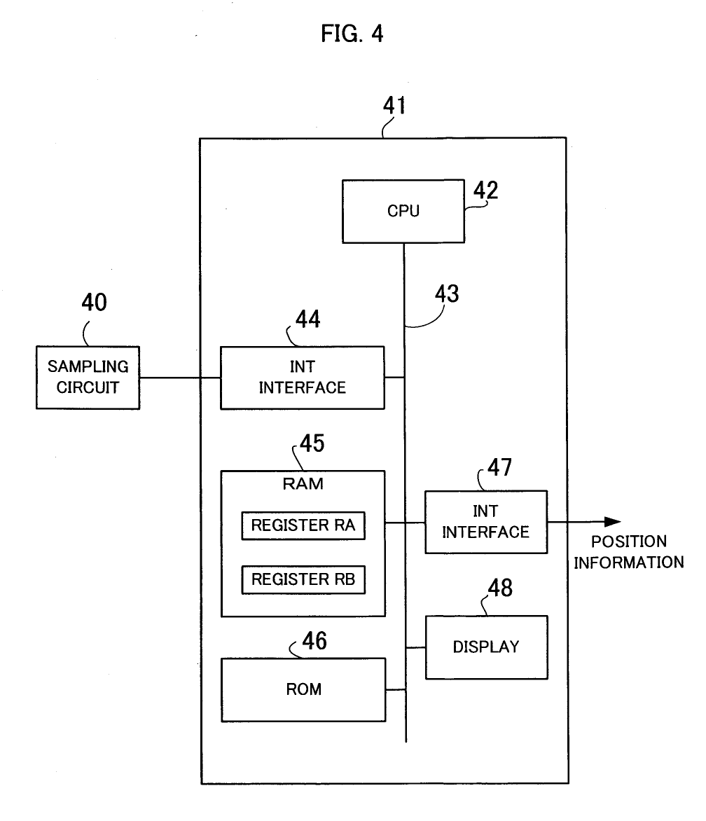

FIG. 4 is a schematic block diagram showing the position detection circuit 41 according to the one embodiment. The position detection circuit 41 includes a first interface 44, RAM 45, ROM 46, second interface 47, and display 48, which are individually connected to a processor 42 therein by a bus 43. The first interface 44 is an interface through which an output signal is received from the sampling circuit 40. The RAM 45 has a storage region for registers RA and RB, which will be described later. Further, the ROM 46 is preloaded with a data table to be used in calculating phase angles. The second interface 47 is an interface through which position data obtained by the position detection circuit 41 is output to the outside. Furthermore, the display 48 is means for displaying the position data. The digital data V_{A} and V_{B} obtained by digitizing the evaluation excitation signals V_{AO} and V_{BO} at the characteristic point of the detection signal V_{SIG} from the sampling circuit 40 are input to the position detection circuit 41 through the first interface 44. As described later, the position detection circuit 41 obtains the phase angles by arc tangent operation or in accordance with the data table.

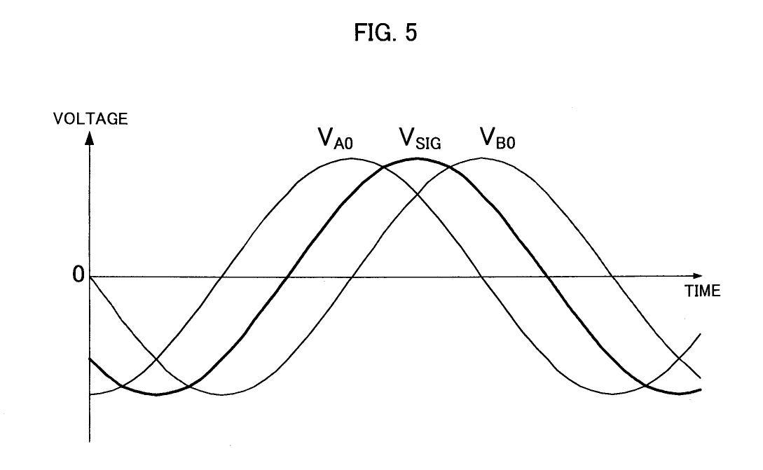

FIG. 5 is a diagram showing the evaluation excitation signals V_{AO} and V_{BO} as reference signals and the amplified detection signal V_{SIG}. Phase differences between the detection signal V_{SIG} and the evaluation excitation signals V_{AO} and V_{BO} change depending on the positional relationship (mechanical phase) between the stationary part 10 and the movable part 20. FIG. 5 shows relationships between the detection signal V_{SIG} and the evaluation excitation signals V_{AO} and V_{BO} at a certain moment. If these signals V_{SIG}, V_{AO} and V_{BO} are observed continuously, the phase differences between the detection signal V_{SIG} and the evaluation excitation signals V_{AO} and V_{BO} do not change when the movable part 20 is stopped with respect to the stationary part 10. When the movable part 20 is moving with respect to the stationary part 10, on the other hand, the phase differences change continuously. If the moving direction (rotation direction) of the movable part 20 is reversed, the orientation of the phase differences also change.

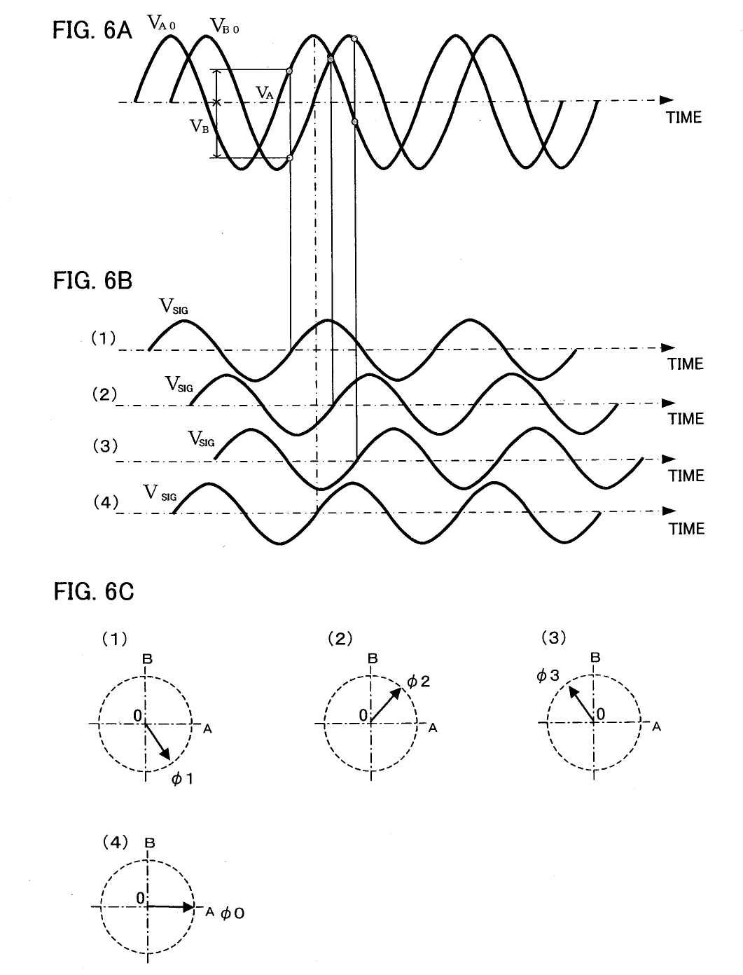

A method for obtaining the phase differences between the detection signal V_{SIG} and the evaluation excitation signals V_{AO} and V_{BO} based on the detection signal V_{SIG} will now be described with reference to FIGS. 6A to 6C.

How to obtain the “detection reference phase” from the detected detection signal V_{SIG} will be explained first. The detection signal V_{SIG} is adjusted in the sampling circuit 40 so that the average value of the detection signal V_{SIG} comes to zero by means of an amplifier for AC coupling, which can remove a DC component from the detection signal V_{SIG}. Then, a zero-cross point where the detection signal V_{SIG} changes from negative to positive is defined as “detection reference phase”. In the sampling circuit 40, the zero-cross point of the detection signal V_{SIG} can be detected by, for example, converting the signal V_{SIG} into a square wave by means of a comparator or limiter amplifier and detecting the rise time of the square wave. The rise time of the square wave is equivalent to the zero-cross point at which the signal V_{SIG} changes from negative to positive.

Then, the voltages of the evaluation excitation signals V_{AO} and V_{BO} are sampled and held by the sample-and-hold circuit (not shown) at the point in time the detection signal V_{SIG} attains the “detection reference phase”. Thereafter, analog signals are converted into digital signals by means of the A/D converter of the sampling circuit 40. By doing this, the evaluation excitation signals V_{AO} and V_{BO} are converted and digitized into digital data. The evaluation excitation signals V_{AO} and V_{BO} acquired at the point in time the detection signal V_{SIG} attains the “detection reference phase” is digitized and those digitized signals V_{AO} and V_{BO} are represented by V_{A} and V_{B}, respectively. The respective amplitudes of the evaluation excitation signals V_{AO} and V_{BO} are previously adjusted to predetermined levels. Alternatively, the evaluation excitation signals V_{AO} and V_{BO} may be normalized by means of separately measured amplitude values after they are digitized.

FIG. 6A shows the evaluation excitation signals V_{AO} and V_{BO}. The abscissa and ordinate of FIG. 6A represent time and voltage, respectively. As mentioned before, the evaluation excitation signals V_{AO} and V_{BO} are two-phase signals, out of the four-phase AC voltages V_{AO} to V_{DO} applied from the excitation power source 30 to the excitation electrodes 11 of the stationary part 10. The phase of the evaluation excitation signal V_{AO} is advanced by a quarter cycle ahead of the signal V_{BO}.

FIG. 6B shows the detection signal V_{SIG} obtained when the position (relative position) of the movable part 20 relative to the stationary part 10 is changed. Graphs (1), (2), (3) and (4) show waveforms of the detection signals V_{SIG} for cases where the movable part 20 is in relative positions 1, 2, 3 and 0, respectively. In each of graphs (1) to (4), the abscissa and ordinate represent time and voltage, respectively. Graphs (1) to (4) indicate that the phase of the detection signal V_{SIG} relative to the evaluation excitation signals V_{AO} and V_{BO} (FIG. 6A) changes if the position of the movable part 20 relative to the stationary part 10 changes.

FIG. 6C shows vectors of which X- and Y-components are the values of the evaluation excitation signals V_{AO} and V_{BO}, respectively. Reference symbols φ1, φ2, φ3, and φ0 in (1), (2), (3) and (4) in FIG. 6C respectively represent vectors indicative of phases when the positions (relative positions) of the movable part 20 relative to the stationary part 10 correspond to (1), (2), (3) and (4) in FIG. 6B, respectively (or when the positions of the movable part 20 relative to the stationary part 10 are in the relative position 1, 2, 3, 0, respectively). These vectors φ1, φ2, φ3 and φ represent phases in which end portions of the coupling electrodes 21 are located if the layout width of the excitation electrode group is deemed to be one cycle. If the phase angles of the vectors φ1, φ2, φ3 and φ0 are calculated by the method mentioned later, the position of the movable part 20 relative to the stationary part 10 within one cycle can be read.

The following is a description of a method for acquiring a phase difference, that is, the position (relative position) of the movable part 20 relative to the stationary part 10, from the digital data V_{A} and V_{B} obtained by converting and digitizing the evaluation excitation signals V_{AO} and V_{BO}. As shown in FIG. 6C, the phase angles φ1, φ2, φ3 and φ0 can be calculated by arc tangent operation given as follows:

φ=a tan 2(V_{B},V_{A})

Here, a tan 2(y, x) is a main value of an arc tangent function prescribed by ANSI Standard, where y is a tangent numerator, and x is a tangent denominator. Since a tan 2(0, 1) is not prescribed by ANSI Standard, it is only necessary that ‘φ=a tan 2(0, 1)=−π’ be defined in the present embodiment. As shown in FIG. 6A (see a vertical dash-dotted line), a relative position (position of the movable part 20 relative to the stationary part 10) φ0 for φ=0 is a position in which V_{A} becomes its positive maximum value when the detection signal V_{SIG} is at the zero-cross point. Alternatively, the values V_{B} and V_{A} may be tabulated so that the value φ can be obtained with reference to a lookup table.

In this case, if a detailed numerical table is to be used to enhance the resolution, it is necessary that the lookup table should be enlarged, but performing interpolation could suppress the size of such lookup table. Finally, the position (relative position) of the movable part 20 relative to the stationary part 10 can be calculated by scaling the table so that a phase difference of 360° (2n radian) is equivalent to the length of each excitation electrode group. Since the sine- and cosine-wave signals are periodic signals of 360°, phase differences of 0° or less or 360° or more cannot be determined by this calculation method. Cases of phase differences of less than 0° or not less than 360° will be described later.

As mentioned before, it is possible to identify the position (phase angle) of one coupling electrode 21 on the movable part 20 within one cycle (called ‘electrical angle’, for descriptive purpose) which corresponds to the length of a single excitation electrode groups 16 on the stationary part 10. However, a plurality of such excitation electrode groups 16 (corresponding to a plurality of cycles) are repeatedly arranged on the stationary part 10, and likewise, a plurality of coupling electrodes 21 are repeatedly arranged on the movable part 20. If the movable part 20 goes across one excitation electrode group 16 on the stationary part 10 to the position of the next excitation electrode group 16, therefore, the same signal as the one obtained when the movable part 20 goes across the preceding excitation electrode group 16 can be obtained. Thereupon, it is possible to count the number of excitation electrode groups 16 across which the movable part 20 has gone, in other words, it is possible to count the number of cycles by which the movable part 10 has passed the excitation electrode groups.

The following is a description of a method for counting the signals generated when the movable part 20 passes the excitation electrode groups 16, thereby determining the number of excitation electrode groups 16 (number of periods) across which the movable part 20 has gone.

First, in capturing the evaluation excitation signals (voltages V_{AO} and V_{BO}) at the zero-cross point of the detection signal V_{SIG} and then obtaining the position (relative position) of the movable part 20 relative to the stationary part 10 from the information (V_{AO}, V_{BO}) at this time point, it is assumed that the absolute value of a variation of the relative position, which is obtained during a time interval between the capture of the preceding relative position information and the capture of the last relative position information, is less than half the length of each excitation electrode group 16.

If the moving speed of the movable part 20 relative to the stationary part 10, a period corresponding to one excitation electrode group 16 cyclically arranged and multiphase-excited, and an acquisition period of for the sine- and cosine-wave signals are VP, L and T, respectively, the following equation is given:

|VP×T|<L×(1/2).

A difference in position, which corresponds to the phase angle φ of 0° to 360°, is equivalent to the period L.

For the value of phase obtained from the sine- and cosine-wave signals acquired periodically, a process to be done when a difference Δφ (=φ(n)−φ(n−1)) between a preceding phase angle φ(n−1) and last phase angle φ(n) falls under any one of the following cases (1) to (3) is explained below. The value range of φ(n) is given by 0≦φ<360°.

(1) Case of |Δφ|<180° (=L/2):

Data in the register RB is not changed. Here, the register RB is storage means for storing data indicative of the number of periods for which the movable part 20 has moved.

(2) Case of Δφ≦180°:

The data in the register RB is incremented by 1, which means the movable part 20 has moved in a positive direction such that the phase angle φ exceeds 360°.

(3) Case of Δφ≧180°:

The data in the register RB is decremented by 1, which means the movable part 20 has moved in a negative direction such that the phase angle φ exceeds 0°.

As described above, rotations of 360° or more can be grasped by counting the repetitions of change in phase difference.

Hereinafter, the phase angle φ between the excitation signal and detection signal, obtained by arc tangent operation, table, or other means, will be referred to as “intra-period phase”. A difference in position corresponding to the length of each excitation electrode group is a phase difference of 360°.

Here, it is assumed that an intra-period phase angle φ[n−1] obtained based on information (V_{AO}, V_{BO}) [n−1] at the time of preceding capture is stored in the register RA. And the difference between the value in the register RA and the value of an intra-period phase angle φ[n] obtained based on information (V_{AO}, V_{BO}) [n] at the time of the last capture is evaluated by using a subtraction circuit or the like.

If the absolute value of the above-mentioned difference (evaluated value) is less than the value of a phase change equivalent to 180°, the value of the last intra-period phase angle φ[n] is stored in the register RA as intra-period phase angle φout, without updating the register RB. As mentioned before, the register RB is a register for storing the multiple of the phase angle of 360° the movable part 20 has moved relative to the stationary part 10.

If the evaluated value is not less than 180°, on the other hand, the value of the last intra-period phase angle φ[n] is stored in the register RA as intra-period phase angle φout, and 1 is subtracted from the data in the register RB.

If the evaluated value is not more than −180°, moreover, the value of the last intra-period phase angle φ[n] is stored in the register RA as intra-period phase angle φout, and 1 is added to the data in the register RB.

Thereafter, by adding the data in the register RA to the data in the register RB, the current relative position obtained from the information at the time of the last capture, from the initial position, is output.

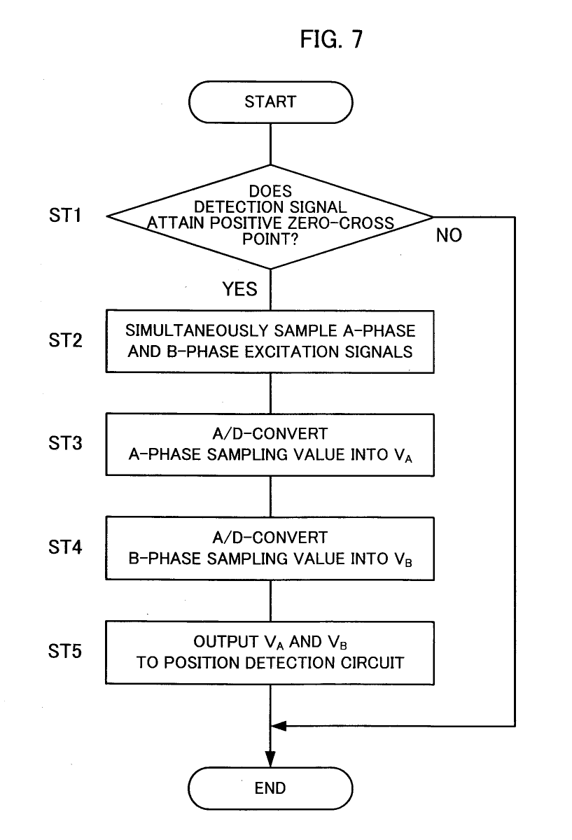

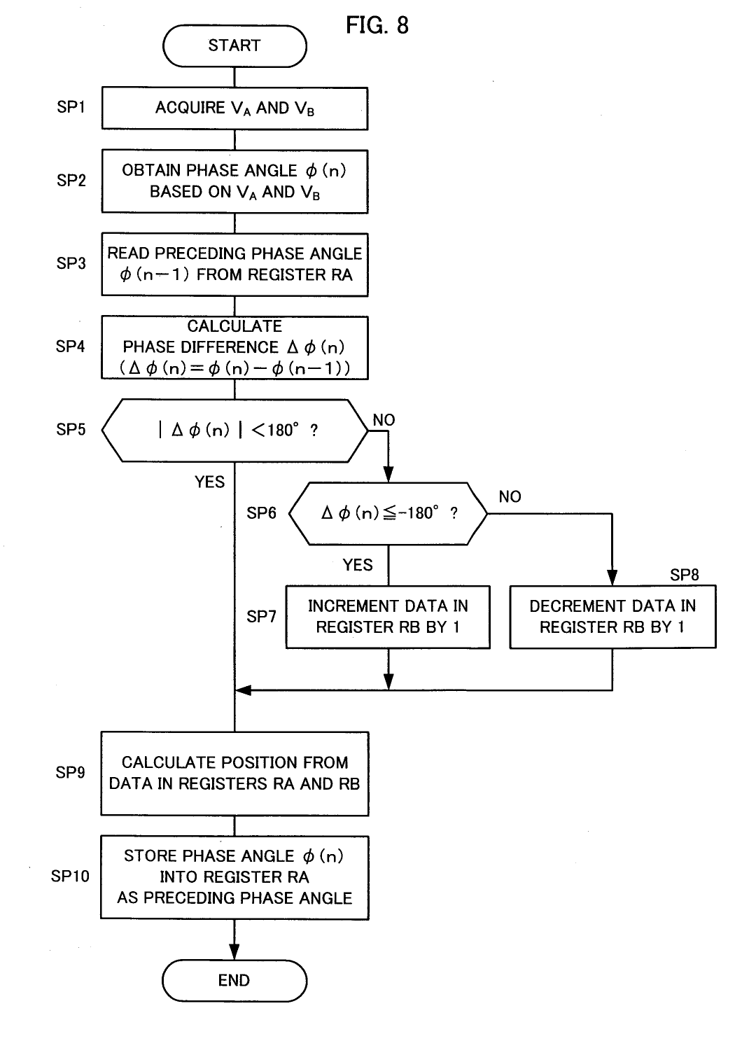

An algorithm of processing for detecting the position of the movable part will now be described with reference to the flowcharts of FIGS. 7 and 8.

FIG. 7 is a flowchart showing an algorithm of processing by the sampling circuit 40 to obtain the values of the evaluation excitation signals at the characteristic point of the detection signal V_{SIG}.

First, it is determined whether or not the detection signal V_{SIG} is at the zero-cross point (positive zero-cross point) where it changes from negative to positive (Step ST1). If the signal V_{SIG} is at the positive zero-cross point, the A- and B-phase excitation signals V_{AO} and V_{BO}, which are evaluation excitation signals, are simultaneously sampled (Step ST2). The A-phase sampling value V_{AO} is A/D-converted into V_{A} (Step ST3), while the B-phase sampling value V_{BO} is A/D-converted into V_{B} (Step ST4). Then, V_{A} and V_{B} are output to the position detection circuit 41 (Step ST5), whereupon this processing is terminated. If it is concluded in Step ST1 that the detection signal V_{SIG} is not at the positive zero-cross point, on the other hand, the processing is terminated without the execution of the process of Step ST2 and the subsequent processes.

FIG. 8 is a flowchart showing an algorithm of processing executed by the position detection circuit 41. This processing is executed for each predetermined processing period.

The values V_{A} and V_{B} output from the sampling circuit 40 are acquired (Step SP1) and, based on the acquired V_{A} and V_{B}, the phase angle φ(n) in the current processing period is obtained with reference to a function or a lookup table (Step SP2). Then, the phase angle φ(n−1) obtained in the preceding processing period is read from the register RA (Step SP3), a calculation, φ(n)−φ(n−1)=Δφ(n), is performed (Step SP4), and it is determined whether or not the absolute value (|Δφ(n)|) of the calculated phase difference Δφ(n) is less than 180° (Step SP5).

If it is concluded in Step SP5 that |Δφ(n)| is not less than 180°, it is further determined whether the calculated phase difference Δφ(n) is not more than −180° (Step SP6).

If it is concluded in Step SP5 that |Δφ(n)| is less than 180°, the program proceeds to Step SP9 without changing the data in the register RB.

If it is concluded in Step SP6 that the phase difference Δφ(n) is not more than −180° (i.e., if a movement beyond one excitation electrode group is caused), the data in the register RB is incremented by 1 (Step SP7). If it is concluded in Step SP6 that the phase difference Δφ(n) is more than −180°, on the hand, the data in the register RB is decremented by 1 (Step SP8). Thereupon, the program proceeds to Step SP9 in either case.

In Step SP9, the relative position of the movable part 20 is calculated based on the data in the registers RA and RB. The data stored in the register RA represents the position of the movable part 20 relative to the stationary part 10 within one period. The data in the register RB represents the multiple of the phase angle of 360° (i.e., number of periods) the movable part 20 has moved relative to the stationary part 10 from the initial position. Since the length of each period is known, the amount of movement (or position) of the movable part 20 relative to the stationary part 10 can be determined by using the data in the registers RA and RB. The phase angle φ(n) obtained in the current processing period (Step SP2) is stored in the register RA (Step SP10) as “preceding phase angle”, whereupon this processing is terminated.

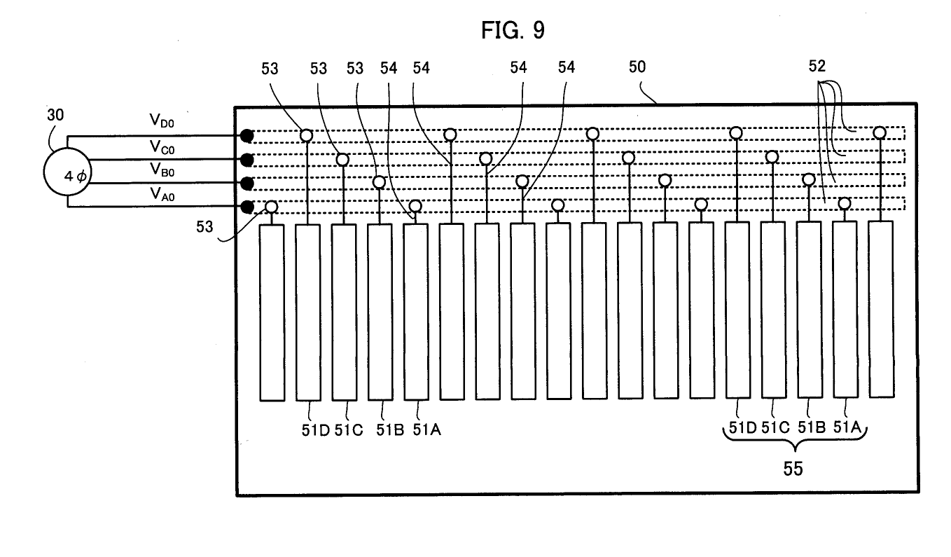

A linear-motion capacitance-type position transducer according to another embodiment of the present invention will now be described with reference to FIGS. 9 to 11. Since the principle of position detection of this linear-motion capacitance-type position transducer 2 is the same as that of the rotary capacitance-type position transducer 1 described above, the following is a description of only an outline of the linear-motion type.

A stationary part 50 used in the linear-motion capacitance-type position transducer 2 will first be described with reference to FIG. 9.

The stationary part 50, like that of the rotary capacitance-type position transducer 1, is configured so that a plurality of excitation electrodes are arranged in a predetermined order and at regular intervals. Four excitation electrodes 51A, 51B, 51C and 51D constitute each excitation electrode group 55. One excitation electrode (e.g., excitation electrode 51A) that constitutes one excitation electrode group 55 is connected to its corresponding excitation electrode (51A) that constitutes another excitation electrode group 55. The number of excitation electrode groups 55 arranged on the stationary part is settled depending on the number of detections.

The stationary part 50, like that of the rotary capacitance-type position transducer 1, is manufactured by, for example, a printed board manufacturing technique. Since the four excitation electrodes 51A to 51D that constitute each excitation electrode group 55 are electrically independent of one another, they are connected to electric conductors 52 by means of a feed conductors 54 and a through-holes 53. In FIG. 9, the electric conductors 52 are depicted by broken lines in order to indicate that they are formed on an inner layer or reverse side of the stationary part 50 with respect to the drawing plane of FIG. 9.

It is required that the stationary part 10 only be made of a rigid board material with an insulating surface. For example, it may be made of a glass-epoxy material, a paper-Bakelite laminate, a ceramic such as glass or alumina, or a metal plate of iron or aluminum or a semiconductor plate of silicon with a ceramic thermally sprayed thereon, coated with an insulating resin, or insulated with an air layer formed by insulating beads.

Conductors such as the electric conductors 52 and feed conductors 54 may be formed by applying photo-etching to a conductive material such as rolled copper foil or vapor-deposited chromium, or by applying ink-jetting, silk screening, or offset printing using conductive ink that contains silver or carbon. The linear-motion capacitance-type position transducer 2, unlike the rotary capacitance-type position transducer 1, is configured so that the stationary part 50 does not have a receiving electrode and, as a result, the output signal from the linear-motion capacitance-type position transducer 2 is output directly from a movable part 70, as mentioned later.

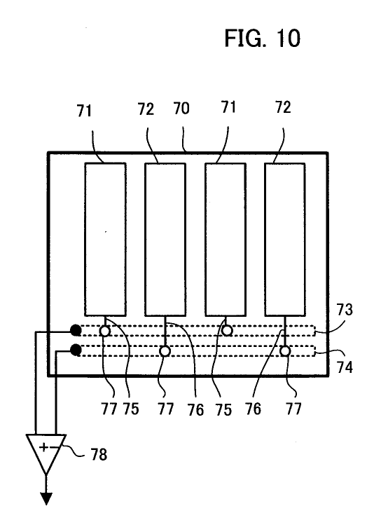

The movable part 70 used in the linear-motion capacitance-type position transducer 2 will now be described with reference to FIG. 10.

A plurality of first coupling electrodes 71 and second coupling electrodes 72 as many as the first coupling electrodes are mounted on one face of the movable part 70 in a manner such that they face the excitation electrodes 51 of the stationary part 50. Each of the first and second coupling electrodes 71 and 72 has a width about half that of each excitation electrode group 55, and these first and second coupling electrodes 71 and 72 are arranged adjacent to one another. In other words, each first coupling electrode 71 faces one half of the excitation electrodes in each excitation electrode group 55, and each second coupling electrode 72 faces the other half of the excitation electrodes in the excitation electrode group 55. In the case of the present embodiment, as shown in FIG. 9, each excitation electrode group 55 includes four excitation electrodes, and a first coupling electrode 71 and a second coupling electrode 72 substantially face two-phase excitation electrodes.

Combination of first coupling electrode 71 and second coupling electrodes 72 forms a coupling electrode group. Further, the number of coupling electrodes arranged are smaller than the number of excitation electrode groups arranged, as a result, whenever the coupling electrodes 71 and 72 are moved relative to the excitation electrode groups 55, the movable part 70 never runs off the stationary part 50, and the area of that parts of the first coupling electrodes 71 which face the excitation electrodes 51 is equal to the area of that parts of the second coupling electrodes 72 which face the excitation electrodes 51.

The first coupling electrodes 71 are connected to a first output electrode 73 through their corresponding electric conductors 75 and electric conductor 77, while the second coupling electrodes 72 are connected to a second output electrode 74 through their corresponding electric conductors 76 and electric conductor 77. The respective voltages of the first and second output electrodes 73 and 74 have mutually a phase difference of 180°, due to the positional relationship between the first and second coupling electrodes 71 and 72. The first and second output electrodes 73 and 74 are connected to a differential amplifier 78. Common-mode noise can be removed to improve noise resistance by obtaining differential components between the outputs of the output electrodes 73 and 74. As in the case of the rotary capacitance-type position transducer 1, moreover, it is possible to make a linear-motion capacitance-type position transducer by using only a single coupling electrode in combination with only a single output electrode. The electric conductors 77 are formed by using the through-hole technique.

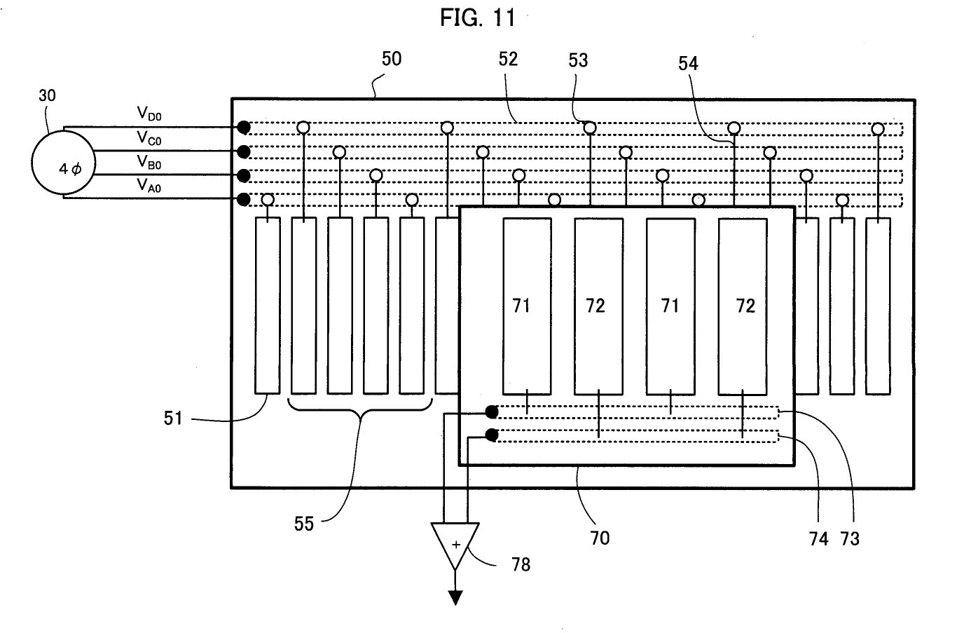

An outline of the linear-motion capacitance-type position transducer 2 with the stationary part 50 and the movable part 70 will now be described with reference to FIG. 11.

The linear-motion capacitance-type position transducer 2 is composed of the stationary part 50, movable part 70, excitation power source 30 that outputs the excitation signals V_{AO}, V_{BO}, V_{CO}, V_{DO} as the four-phase AC voltages, and differential amplifier 78 that receive a detection output. The four-phase AC voltages with phases mutually shifted by quarter-period from one another are applied individually to the four excitation electrodes 51 (51A, 51B, 51C, 51D) on the stationary part 50. The movable part 70 is supported by a mechanical section (not shown) for lateral movement, as viewed in FIG. 11, with a predetermined gap kept between the excitation electrodes 51 of the stationary part 50 and that surface thereof on which the first and second coupling electrodes 71 and 72 are located.

In the rotary or linear-motion capacitance-type position transducer of the present invention, as described above, the relative positions of the stationary part with respect to the movable part can be detected with high resolution by interpolating the detection signal obtained from the movable part.

In the capacitance-type position transducer with the four excitation electrodes according to the present invention, as described before, the intra-period phase angle φ is calculated from the two excitation signals V_{AO} and V_{BO} with the phase difference of 90° captured at the point in time the phase of the detection signal V_{SIG} attains the characteristic point (e.g., zero-cross point), with reference to the function, a tan 2(y, x), and lookup table.

The following is a description of a generalized case, not the case where the number of phases of the excitation reference signals and phase differences between the reference signals are at the above-described specific values. More specifically, the intra-period phase φ is estimated by a statistical method (method of least squares in this case) based on the values of phases 1 to n of the excitation reference values captured at the point in time the phase of the detection signal V_{SIG} attains the characteristic point and previously known parameters of the excitation signals in the individual phases. For this estimation, it is assumed that the plurality of reference signals have the same frequency and known intrinsic phase differences and the relationships between the intra-period phase φ and amplitudes is defined in advance.

In a relational expression for each reference signal and the intra-period phase φ, value of φ is varied from 0 to 2π radians at a predetermined pitch, and, as a result, the value of φ with a minimum difference from a read reference signal value is used as an intra-period phase.

If the number of reference signals for the capture of data is m and if the reference signals are V₁₀, V₂₀, . . . Vₘ₀, for example, the reference signals with the intra-period phase φ are given by

$$\begin{matrix}{V}_{10} ( ϕ ) = A 1 ( cos ( ω t + θ 1 + ϕ ) ) , \\ {V}_{20} ( ϕ ) = A 2 ( cos ( ω t + θ 2 + ϕ ) ) , \\ ⋮ \\ {V}_{m 0} ( ϕ ) = Am ( cos ( ω t + θ m + ϕ ) ) .\end{matrix}$$

Here An is an amplitude of each reference signal, and θn (n=1 to m) is a phase difference intrinsic to each reference signal.

Let it be supposed that data on the reference signals captured at the point in time the phase of the detection signal V_{SIG} attains the characteristic point are V1, V2, Vm. In order to obtain φ from these data V1, V2, Vm, the value of φ is varied from 0 to 2π radians at the predetermined pitch in the equations for V₁₀(φ) to Vₘ₀(φ), and the following calculation is performed. In order to avoid confusion with the actual intra-period phase φ, φ which is varied in accordance with the equations for V₁₀(φ) to Vₘ₀(φ) is represented by φ*. Here, ωt is known information obtained from the excitation power source, and θ1 to θm are also known.

$$\begin{matrix}E 1 ( {ϕ}^{*} ) = {\{ V 1 - V 10 ( {ϕ}^{*} ) \}}^{2} , \\ E 2 ( {ϕ}^{*} ) = {\{ V 2 - V 20 ( {ϕ}^{*} ) \}}^{2} , \\ ⋮ \\ Em ( {ϕ}^{*} ) = {\{ Vm - Vm 0 ( {ϕ}^{*} ) \}}^{2} , \\ E ( ϕ ) = {\sum }_{n - 1}^{m} {E}_{n} ( {ϕ}^{*} ) ,\end{matrix}$$

The value of φ* which makes the value E(φ) minimum is assumed to be an estimated intra-period phase φ. A positive or negative zero-cross point can, for example, be used as a characteristic point of the detection signal V_{SIG}.

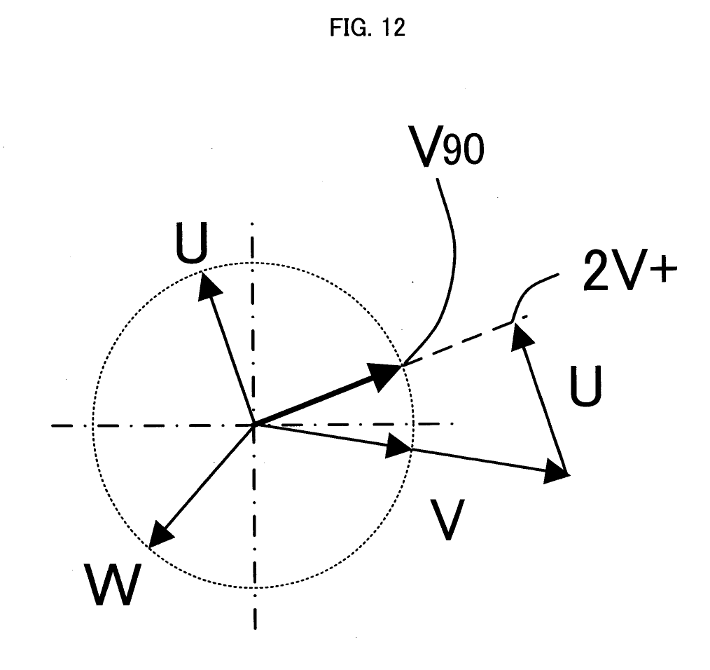

The following is a description of an embodiment in which the relative phase difference between two excitation signals is not specified to 90°. If the phase difference between two excitation signals is neither 0° nor 180°, these two excitation signals can be converted into signals with a 90° difference. If there are three-phase excitation signals U, V and W with the same amplitude and phase differences of 120°, for example, the excitation signals U and V have a phase difference of 120° from each other. If conversion is made in accordance with V₉₀=(1/√3)×(2×V+U), where U and V are vectors, a signal V₉₀ with a phase difference of 90° from the signal U is obtained (see FIG. 12). Therefore, the signal with a phase difference of 90° can be obtained by converting (real parts of) the reference signals U and V that are captured at the point in time the phase of the detection signal attains the characteristic point. The relative phases of the stationary part and the movable part can be obtained by applying an arc tangent operation or lookup table processing to the signal with 90° phase difference.

What is claimed is:

1. A capacitance-type position transducer comprising a stationary part and a movable part, the movable part facing the stationary part and configured to move relative to the stationary part, wherein
said stationary part includes a plurality of excitation electrode groups, each composed of a plurality of excitation electrodes arranged cyclically and electrically independent of one another, and a receiving electrode electrically independent of the excitation electrode groups,
said movable part includes a plurality of coupling electrodes which face the excitation electrode groups and are arranged cyclically and a transmitting electrode which is electrically connected with all the coupling electrodes and faces the receiving electrode,
a signal of which the phase changes depending on relative positions of the movable part with respect to the stationary part is detected as a detection signal from said receiving electrode when a plurality of excitation signals of the same frequency and different phases are applied individually to the plurality of excitation electrodes, and
said capacitance-type position transducer further comprising:
phase difference calculating means for calculating a phase difference between said detection signal and an arbitrarily selected one of the excitation signals, based on the values of the plurality of excitation signals at a point in time the phase of the detection signal attains the characteristic point; and
position calculating means for calculating a position of the movable part relative to the stationary part from the phase difference calculated by said phase difference calculating means.

2. The capacitance-type position transducer according to claim 1, wherein said phase difference calculating means calculates the phase difference between the detection signal and the arbitrarily selected excitation signal, based on values of two of the excitation signals with a phase difference therebetween of neither 0° nor 180°, at a point in time the phase of the detection signal attains the characteristic point.

3. The capacitance-type position transducer according to claim 2, wherein said characteristic point of the phase of the detection signal is a zero-cross point at which a signal obtained by removing a DC component from the detection signal changes from negative to positive, and said two of the excitation signals with a phase difference therebetween of neither 0° nor 180° are two excitation signals with a phase difference therebetween of 90°.

4. The capacitance-type position transducer according to claim 1, which further comprises first storage means for storing the number of frequencies of the excitation electrode groups corresponding to the position of the movable part relative to the stationary part and second storage means for storing position data on the movable part within the excitation electrode groups, wherein,
on the condition that the amount of movement of the movable part during a time interval for the position calculating means to calculate the position of the movable part is less than half the period of each of the excitation electrode groups,
if a position variation obtained by subtracting immediately previously calculated position data on the movable part, stored in the second storage means, from the last calculated position data is more than a negative half of and less than a positive half of an arrangement cycle of the excitation electrode groups, then the data stored in the second storage means is updated to last calculated position data on the movable part without updating the data stored in the first storage means,
if said position variation is not more than the negative half of the arrangement cycle of the excitation electrode groups, then one period is added to the data stored in the first storage means, and,
if the position variation is not less than the positive half of the arrangement cycle of the excitation electrode groups, then one period is subtracted from the data stored in the first storage means and the data stored in the second storage means is updated to the last calculated position data,
whereby the position of the movable part is obtained based on the frequencies stored in the first storage means and said last calculated position data.
